(19) United States
(12) Patent Application Publication
(10) Pub. No.: US 2025/0227846 A1
(43) Pub. Date: Jul. 10, 2025

(54) WIRING BOARD

(71) Applicant: Murata Manufacturing Co., Ltd., Nagaokakyo-shi (JP)

(72) Inventor: Yasuhiro TANAKA, Nagaokakyo-shi (JP)

(21) Appl. No.: 19/089,550

(22) Filed: Mar. 25, 2025

Related U.S. Application Data
(63) Continuation of application No. PCT/JP2023/032240, filed on Sep. 4, 2023.
(60) Provisional application No. 63/411,770, filed on Sep. 30, 2022.

(51) Int. Cl. H05K 1/14; H05K 1/02

(52) U.S. Cl. CPC H05K 1/142; H05K 1/0283; H05K 2201/0129; H05K 2201/09236

(57) ABSTRACT

A wiring board that includes: a first substrate having a first main surface; a second substrate having a second main surface; a first wiring on the first main surface; and a second wiring on the second main surface. The first main surface and the second main surface are in contact with each other, and the first substrate and the second substrate are connected to each other. The first wiring and the second wiring face each other in a thickness direction of the first substrate and are electrically connected to each other.

### CROSS REFERENCE TO RELATED APPLICATIONS

The present application is a continuation of International application No. PCT/JP2023/032240, filed Sep. 4, 2023, which claims priority to Provisional Patent Application No. 63/411,770, filed Sep. 30, 2022, the entire contents of each of which are incorporated herein by reference.

### TECHNICAL FIELD

The present disclosure relates to a stretchable wiring board.

### BACKGROUND ART

Conventionally, as a wiring board, there is one described in Japanese Patent Application Laid-Open No. H7-94861 (Patent Document 1). In this wiring board, a heat-adhesive insulating resist is formed on a first substrate and a second substrate, an electrode pattern is formed on the insulating resist, the electrode patterns of the substrates are caused to face each other and brought into pressure contact with each other, and a resist around the electrode pattern is heat-bonded in a pressure contact state. As described above, the wiring board has two insulating resist layers between the first substrate and the second substrate. The first substrate and the second substrate are connected with two insulating resist layers interposed therebetween.

### SUMMARY OF THE DISCLOSURE

In the conventional wiring board, since there are two insulating resist layers between the first substrate and the second substrate, there is a problem that the wiring board becomes thick.

Therefore, an object of the present disclosure is to provide a wiring board that can be thinned.

In order to achieve the above object, a wiring board according to one aspect of the present disclosure includes: a first substrate having a first main surface; a second substrate having a second main surface; a first wiring on the first main surface; and a second wiring on the second main surface. The first main surface and the second main surface are in contact with each other, and the first substrate and the second substrate are connected to each other. The first wiring and the second wiring face each other in a thickness direction of the first substrate and are electrically connected to each other.

According to the wiring board according to one aspect of the present disclosure, it is possible to reduce thickness.

### BRIEF EXPLANATION OF THE DRAWINGS

FIG. 1 is an exploded perspective view of a wiring board according to a first embodiment of the present disclosure.

FIG. 2 is an exploded plan view of the wiring board.

FIG. 3 is a plan view of the wiring board.

FIG. 4 is a sectional view taken along IV-IV of FIG. 3.

FIG. 5 is a sectional view taken along V-V of FIG. 3.

FIG. 6A is a sectional view for explaining a method of manufacturing the wiring board.

FIG. 6B is a sectional view for explaining the method of manufacturing the wiring board.

FIG. 7 is a sectional view of the wiring board according to a second embodiment of the present disclosure.

FIG. 8A is a sectional view for explaining a method of manufacturing the wiring board.

FIG. 8B is a sectional view for explaining the method of manufacturing the wiring board.

FIG. 9 is a plan view of the wiring board according to a third embodiment of the present disclosure.

FIG. 10 is a sectional view taken along X-X of FIG. 9.

FIG. 11 is a sectional view of the wiring board according to a fourth embodiment of the present disclosure.

FIG. 12 is a sectional view of the wiring board according to a fifth embodiment of the present disclosure.

FIG. 13 is a sectional view of a first variation of the wiring board according to the fifth embodiment.

FIG. 14 is a sectional view of a second variation of the wiring board according to the fifth embodiment.

FIG. 15 is a sectional view of the wiring board according to a sixth embodiment.

FIG. 16 is a plan view of the wiring board according to a seventh embodiment.

FIG. 17 is a sectional view taken along XVII-XVII of FIG. 16.

FIG. 18 is a sectional view of the wiring board according to an eighth embodiment.

FIG. 19 is a sectional view of the wiring board according to a ninth embodiment.

FIG. 20 is a sectional view of the wiring board according to a tenth embodiment.

### DESCRIPTION OF THE PREFERRED EMBODIMENTS

Hereinafter, an embodiment of the present disclosure will be described in detail with reference to the drawings. Mainly described in each of the embodiments is a point different from a point already described before the embodiment. Particularly, similar functions and effects achieved by similar configurations will not be mentioned sequentially for each of the embodiments. Among constituent elements in an embodiment below, a constituent element not described in an independent claim is described as an optional constituent element. Further, size and a ratio of size of constituent elements illustrated in the drawings are not necessarily strict. Further, in the drawings, substantially the same configurations are denoted by the same reference symbols, and redundant description may be omitted or simplified.

### First Embodiment

### (Structure)

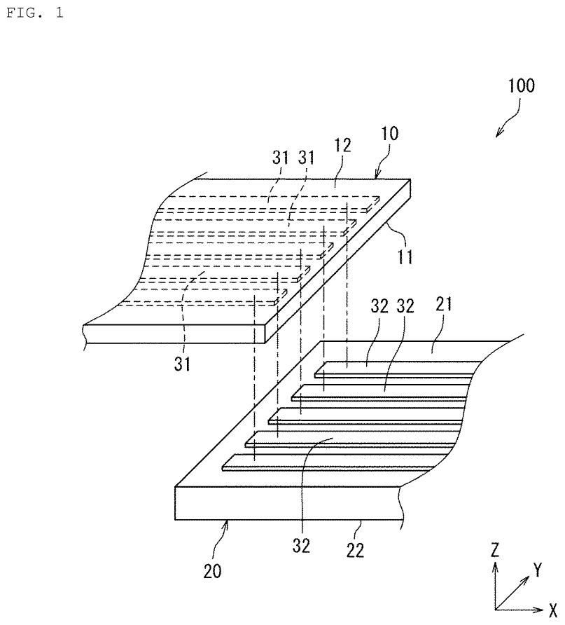

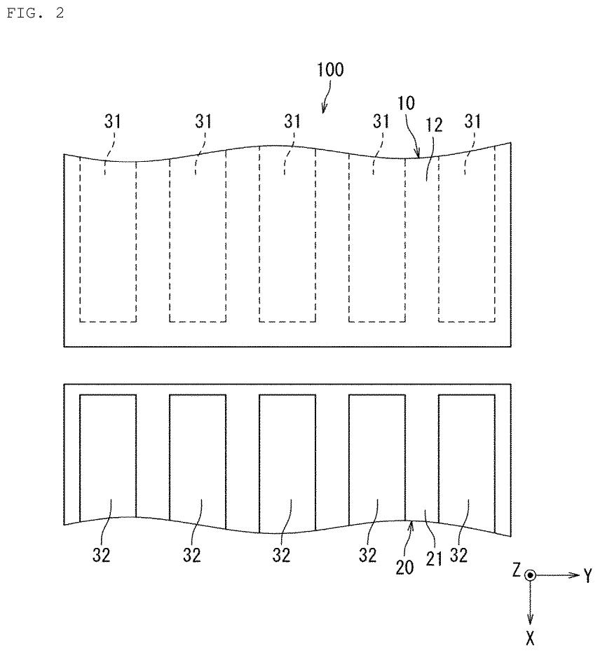

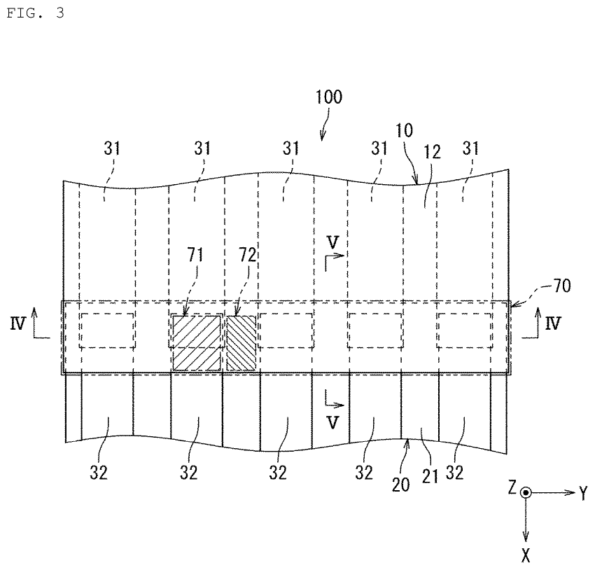

A structure of a wiring board according to a first embodiment will be described with reference to FIGS. 1, 2, 3, 4, and 5. FIG. 1 is an exploded perspective view of the wiring board according to the first embodiment of the present disclosure. FIG. 2 is an exploded plan view of the wiring board. FIG. 3 is a plan view of the wiring board. FIG. 4 is a sectional view taken along IV-IV of FIG. 3. FIG. 5 is a sectional view taken along V-V of FIG. 3.

In the drawings of the present description, a direction parallel to a thickness direction of a first substrate and from a first main surface to a third main surface of the first substrate is indicated by an arrow Z. The thickness direction may include both a forward Z direction and a reverse Z direction. In this embodiment, a thickness direction of a second substrate is also parallel to the Z direction. Further, a direction parallel to an extending direction of the first substrate and directed from a position away from the second substrate to a position close to the second substrate in the first substrate is indicated by an arrow X. The extending direction of the first substrate may include both a forward X direction and a reverse X direction. In this embodiment, an extending direction of a first wiring, the second substrate, and a second wiring is also parallel to the X direction. The X direction and the Z direction are orthogonal to each other, and a direction orthogonal to the X direction and the Z direction is defined as a Y direction. When X, Y, and Z are arranged in this order, a right-handed system is formed.

A wiring board 100 includes a first substrate 10 having a first main surface 11, a second substrate 20 having a second main surface 21, a first wiring 31 arranged on the first main surface 11, and a second wiring 32 arranged on the second main surface 21. The wiring board 100 is used, for example, for circuit connection with a printed circuit board or a flexible board.

The first substrate 10 is a support material such as a film material made from a stretchable resin material. The shape of the first substrate 10 is a sheet shape or a film shape. The first substrate 10 has the first main surface 11 and a third main surface 12 located on the opposite side to each other.

The first substrate 10 has a recessed portion 14 on the first main surface 11 (see FIG. 4). The recessed portion 14 exists at least in a region 70 where the first substrate 10 and the second substrate 20 overlap when viewed from the Z direction. The recessed portion 14 corresponds to a portion where the first substrate is recessed in the Z direction (that is, a thickness direction of the first substrate 10) on the first main surface 11. For this reason, an inner surface of recessed portion 14 can also be understood as a surface that forms a recess of first main surface 11. The first main surface 11 may include an inner surface of the recessed portion 14 and a flat surface other than the recessed portion 14. The recessed portion 14 may extend along the X direction. There can be a plurality of the recessed portions 14. A plurality of the recessed portions 14 may be arranged in parallel to each other along the Y direction. The third main surface 12 is an exposed surface in the present embodiment.

Examples of a material of the first substrate 10 include thermoplastic resin and the like. Specifically, a material of the first substrate 10 is a stretchable resin material, and includes, for example, styrene resin, olefin resin, epoxy resin, urethane resin, acrylic resin, and/or silicone resin. More specifically, thermoplastic polyurethane (TPU), polyethylene (PE), and the like are included. Further, the resin material preferably has a softening point. Specifically, the softening point is more preferably 90° C. or more. By the above, the first main surface 11 of the first substrate 10 and the second main surface 21 of the second substrate 20 easily come into contact with each other.

The first substrate 10 has stretchability. Since the first substrate 10 has stretchability, it is possible to reduce the risk of breakage in expansion and contraction of the wiring board 100 during use. Thickness of the first substrate 10 is not particularly limited, but is preferably 160 μm or less, and more preferably 80 μm or less, from the viewpoint of not inhibiting expansion and contraction of a surface of a living body at the time of attachment to the living body. Further, the thickness of the first substrate 10 is preferably 40 μm or more.

The second substrate 20 has the second main surface 21 and a fourth main surface 22 located on the opposite side to each other. When viewed from the Z direction, an end portion in the X direction of the second substrate 20 overlaps an end portion in the X direction of the first substrate 10. More specifically, an end portion in the reverse X direction of the second substrate 20 overlaps an end portion in the forward X direction of the first substrate 10. The second main surface 21 faces the first main surface 11. In the present embodiment, the fourth main surface 22 is an exposed surface. Note that the fourth main surface 22 does not need to be exposed.

In the present embodiment, the second substrate 20 is a substrate different from the first substrate 10, and is, for example, a rigid board, a flexible board, or the like. As the rigid substrate, for example, a glass epoxy board produced by impregnating epoxy resin into a stack of glass fiber fabrics is used. As the flexible board, for example, polyimide which is plastic having excellent heat resistance is used.

When the second main surface 21 of the second substrate 20 and the first main surface 11 of the first substrate 10 are brought into contact with each other, the first substrate 10 and the second substrate 20 are connected to each other (see FIG. 3). By the above, the wiring board 100 can be reduced in thickness. That is, since the first substrate 10 and the second substrate 20 are directly in contact with and connected to each other without requiring an insulating resist, thickness of the entire device can be reduced by thickness of the insulating resist as compared with contact with the insulating resist interposed therebetween in a conventional technique. Further, since the insulating resist is unnecessary, printing of the insulating resist is also unnecessary. By the above, manufacturing cost and man-hours of the wiring board can be reduced.

Preferably, the first main surface 11 of the first substrate 10 and the second main surface 21 of the second substrate 20 are in contact with and bonded to each other. The bonding is, for example, thermocompression bonding, welding, fusion bonding, or the like. In the region 70 where the first substrate 10 and the second substrate 20 overlap, at least a part of the first main surface 11 and the second main surface 21 only needs to be in contact with and bonded to each other.

Here, bonding means being able to withstand tensile force of 20 N. The bonding strength between the first substrate 10 and the second substrate 20 can be evaluated based on JIS K 6849. Being in contact with and bonded means that the first main surface 11 of the first substrate 10 and the second main surface 21 of the second substrate 20 are directly bonded to each other without another member such as an adhesive interposed therebetween.

Therefore, since the first substrate 10 and the second substrate 20 come into contact with each other by surface contact between the first main surface 11 and the second main surface 21, connection strength between the first substrate 10 and the second substrate 20 is improved. Note that a method for bringing the first main surface and the second main surface into contact with each other is not particularly limited, but for example, the first substrate 10 and the second substrate 20 may be connected to side surfaces of the first substrate 10 and the second substrate 20 with another member interposed therebetween, so that the first main surface and the second main surface are in contact with each other.

In a case where a position of an interface between the first main surface 11 and the second main surface 21 cannot be determined in a region where the first main surface 11 and the second main surface 21 are in contact with each other, a portion where an extended surface extended from a non-overlapping surface not overlapping the second main surface 21 in the first main surface 11 so as to be flush with the non-overlapping surface overlaps a region where the first main surface 11 and the second main surface 21 are in contact with each other is defined as the interface. As illustrated in FIG. 5, an extended surface 11b of a flat surface 11a (non-overlapping surface) of the first main surface 11 located in a region where the first main surface 11 and the second main surface 21 are not in contact with each other is defined as an interface between the first main surface 11 and the second main surface 21. In other words, the extended surface 11b is a surface that is substantially flush with the flat surface 11a in a contact region between the first substrate 10 and the second substrate 20. Note that, needless to say, the extended surface is a virtual plane. The same applies to an embodiment that follows.

The first wiring 31 is arranged on the first main surface 11 of the first substrate 10. At least in the region 70 where the first substrate 10 and the second substrate 20 overlap, the first wiring 31 has a shape extending in one direction. Specifically, the first wiring 31 may extend along the X direction. There may be a plurality of the first wirings 31. A plurality of the first wirings 31 may be arranged in parallel to each other along the Y direction. Note that a shape of the first wiring 31 is not particularly limited.

The first wiring 31 is formed of a conductive material. As the conductive material, for example, metal foil of silver, copper, nickel, or the like may be used, or a mixture of metal powder of silver, copper, nickel or the like and elastomeric resin such as epoxy resin or silicone resin may be used. The first wiring 31 preferably has stretchability.

The first wiring 31 is arranged in the first recessed portion 14 of the first substrate 10. The first wiring 31 may be arranged so as to be fitted into the first recessed portion 14 on the first main surface 11. This can also be understood that the first wiring 31 is arranged in the first recessed portion 14 and extends along the first recessed portion 14. Further, one of the first wirings 31 is arranged in one of the first recessed portions 14. That is, each of a plurality of the first wirings 31 may be separately arranged in each of a plurality of the first recessed portions 14. According to such a structure, the first substrate 10 exists between two of the first wirings 31 adjacent to each other in the Y direction. This makes it possible to ensure insulation between two of the first wirings 31 adjacent to each other. From the viewpoint of reducing thickness of the entire wiring board, thickness of the first wiring 31 is preferably 30 μm or less.

The second wiring 32 is arranged in the first recessed portion 14 of the first substrate 10. At least in the region 70 where the first substrate 10 and the second substrate 20 overlap, the second wiring 32 has a shape extending in one direction. Specifically, the second wiring 32 may extend along the X direction. There may be a plurality of the second wirings 32. A plurality of the second wirings 32 may be arranged in parallel to each other in the Y direction. Note that a shape of the second wiring 32 is not particularly limited.

The second wiring 32 is formed of a conductive material. As the conductive material, for example, metal foil of silver, copper, nickel, or the like may be used, or a mixture of metal powder of silver, copper, nickel or the like and elastomeric resin such as epoxy resin or silicone resin may be used. Preferably, the second wiring 32 has stretchability.

The first wiring 31 and the second wiring 32 face each other in the Z direction (thickness direction of the first substrate) and are electrically connected. Specifically, the first wiring 31 and the second wiring 32 are in direct contact with and electrically connected to each other. Note that the first wiring 31 and the second wiring 32 may be electrically connected via a conductive member arranged between the first wiring 31 and the second wiring 32.

Preferably, the second wiring 32 may be in contact with the first wiring 31 arranged in the first recessed portion 14. At this time, the first wiring 31 and the second wiring 32 may be in contact with each other at the first recessed portion 14 in sectional view. On the other hand, the first main surface 11 and the second main surface 21 may be in contact with each other on a flat surface of the first main surface 11 (see FIG. 4). In such a structure, in sectional view, an interface between the first wiring 31 and the second wiring 32 and an interface between the first main surface 11 and the second main surface 21 are located on different planes. Since an interface between the first wiring 31 and the second wiring 32 and an interface between the first substrate 10 and the second substrate 20 are located on different planes in sectional view, strength against peeling on a bonding surface between the first substrate 10 and the second substrate 20 may be improved.

As illustrated in FIG. 4, in the region 70 where the first substrate 10 and the second substrate 20 overlap, a plurality of the second wirings 32 are arranged side by side in the Y direction. Preferably, a ratio L1/L2 between a width L1 of the second wiring 32 and a width L2 between two of the second wirings 32 adjacent to each other in the Y direction is 1 to 20. When the ratio of L1/L2 is 20 or less, insulation between two of the second wirings 32 adjacent to each other can be suitably ensured. Further, by sufficiently securing a contact area between the first main surface 11 and the second main surface 21, connection strength between the first substrate 10 and the second substrate 20 is improved. When the ratio of L1/L2 is 1 or more, a larger one of the second wiring 32 can be ensured, and electrical resistance of the second wiring 32 can be reduced. Note that, among a plurality of the second wirings 32, at least two of the second wirings 32 adjacent to each other in the Y direction only need to satisfy the above configuration, and preferably all the second wirings 32 satisfy the above configuration. Similarly, a width of the first wiring 31 and a distance between two of the first wirings 31 adjacent to each other also more preferably satisfy the above relationship.

Here, the width L1 of the second wiring 32 is size in a direction orthogonal to an extending direction of the second wiring 32 when viewed from the Z direction. That is, the width L1 of the second wiring 32 is size in the Y direction of the second wiring 32. The width L1 of the second wiring 32 is a maximum value of a width of the second wiring 32. In a case where it is difficult to measure a maximum value in the second wiring 32, an average value of widths of the second wirings 32 is set to L1. A width of the first wiring 31 may be the same as the width L1 of the second wiring 32.

Similarly, the width L2 between two of the second wirings 32 adjacent to each other in the Y direction is a shortest distance in the Y direction between two of the second wirings 32 adjacent to each other in the Y direction. In a case where it is difficult to measure a shortest distance in the Y direction between the second wirings 32, an average value of widths between two of the second wirings 32 adjacent to each other in the Y direction is set to L2.

The average value refers to an average value of measurement values obtained by measuring widths at three different points along the extending direction (X direction) with respect to one of the second wiring 32 in a region where the first substrate 10 and the second substrate 20 overlap.

As illustrated in FIG. 3, in the region 70 where the first substrate 10 and the second substrate 20 overlap as viewed in the thickness direction (Z direction) of the first substrate, a plurality of the second wirings 32 are arranged side by side in the Y direction. In the region 70, a ratio S1/S2 of an area S1 of a region 71 (hereinafter, referred to as the first region 71) where the second wiring 32 is present to an area S2 of a region 72 (hereinafter, referred to as a second region 72) between two of the second wirings 32 adjacent to each other in the Y direction is preferably 1 to 20.

Here, the first region 71 is a region of one of the second wirings 32 in the region 70 where the first substrate 10 and the second substrate 20 overlap when viewed from the Z direction. The second region 72 is a region between two of the first regions 71 adjacent to each other in the Y direction when viewed from the Z direction. In FIG. 3, for convenience, the first region 71 and the second region 72 are indicated by hatching. Each of the first region 71 and the second region 72 may have a rectangular shape. In the X direction, lengths of the first region 71 and the second region 72 are the same. Note that a shape of the first region 71 and the second region 72 is not limited to a rectangular shape.

When the ratio S1/S2 is 20 or less, insulation between two of the second wirings 32 adjacent to each other can be suitably ensured. Further, a contact area between the first main surface 11 and the second main surface 21 can be ensured. By the above, connection strength between the first substrate 10 and the second substrate 20 is improved. Further, when the ratio S1/S2 is 1 or more, a larger one of the second wiring 32 can be arranged, so that the electric resistance of the second wiring 32 can be reduced.

Preferably, in the Z direction, a distance D1 from the first wiring 31 to the third main surface 12 of the first substrate 10 is smaller than a distance D2 from an interface between the first substrate 10 and the second substrate 20 to the third main surface 12 of the first substrate 10 (see FIG. 4). The distance D1 refers to a minimum value between the first wiring 31 and the third main surface 12, and the distance D2 refers to a minimum value between an interface between the first substrate 10 and the second substrate 20 and the third main surface 12. By this, a shape of the third main surface 12 of the first substrate 10 can be made flatter. Preferably, the distance D2 is equal to or more than the sum of thickness of the first wiring 31 and thickness of the second wiring 32. Further, by making the distance D1 small, thickness of the first substrate 10 at a portion overlapping the first wiring 31 when viewed from the Z direction can be made small. When viewed from the Z direction, a substrate at a portion overlapping a wiring is predicted to have reduced stretchability. According to the above structure, thickness of a substrate at a portion where reduction in stretchability is predicted can be made small, so that when the first substrate 10 has stretchability, the stretchability of the first substrate 10 is excellent.

### (Manufacturing Method)

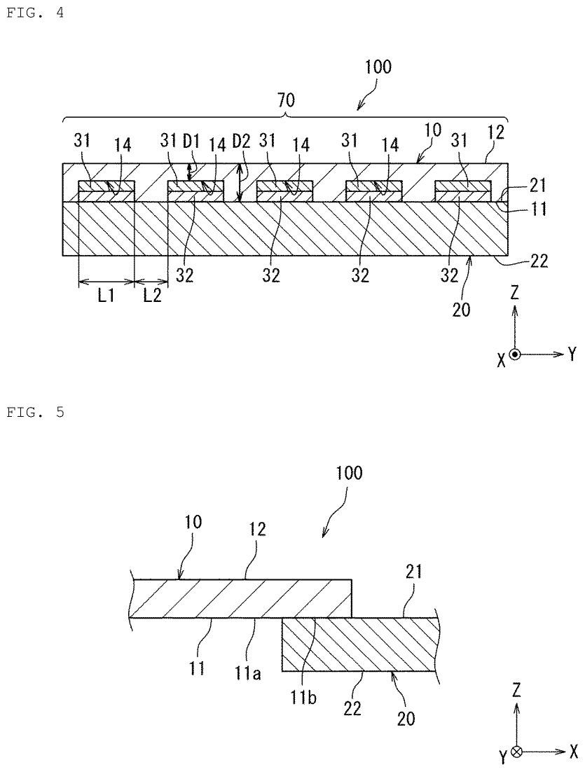

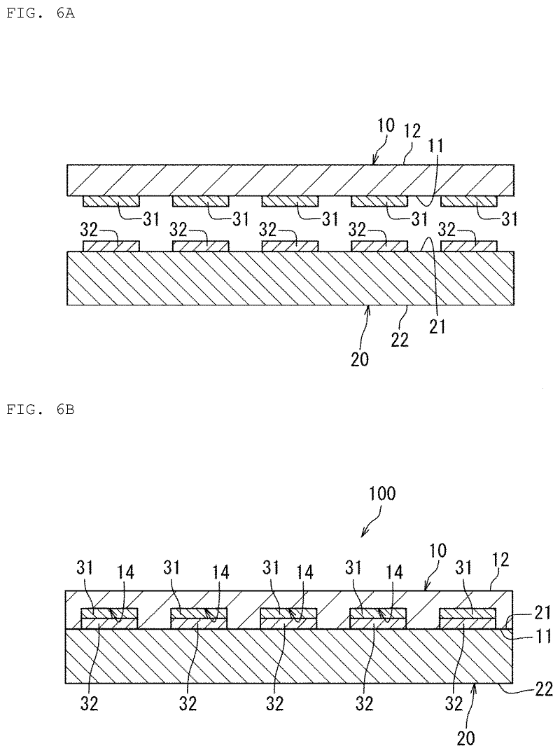

Next, an exemplary method of manufacturing the wiring board 100 will be described with reference to FIGS. 6A and 6B.

As illustrated in FIG. 6A, a plurality of the first wirings 31 are formed on the first main surface 11 of the first substrate 10. Similarly, a plurality of the second wirings 32 are formed on the second main surface 21 of the second substrate 20. The first substrate 10 and the second substrate 20 are stacked in a manner that the first wiring 31 and the second wiring 32 face each other in the Z direction (that is, a thickness direction of the substrate). Then, the first substrate 10 and the second substrate 20 stacked on each other are thermocompression-bonded. This may be performed, for example, by pressing a heater against the third main surface 12 of the first substrate 10.

As illustrated in FIG. 6B, by pressurization and heating by a heater, the first substrate 10 flows into a space where no wiring is arranged, such as a space between a plurality of wirings adjacent to each other in the Y direction. The first substrate 10 that flows comes into contact with the second substrate 20 while covering the first wiring 31 and the second wiring 32. By this, the first main surface 11 of the first substrate 10 and the second main surface 21 of the second substrate 20 are thermocompression-bonded, and the first wiring 31 and the second wiring 32 are arranged in the first recessed portion 14. Since the first substrate 10 has a softening point, the first substrate 10 easily flows when heated, and easily comes into contact with the second substrate 20. That is, the first substrate 10 has a softening point suitable for thermocompression bonding. Further, since the first substrate 10 has thermoplasticity, which is similarly suitable for thermocompression bonding. Note that a method of thermocompression bonding is not particularly limited, and for example, another heater may be pressed against the fourth main surface 22 of the second substrate 20.

### Second Embodiment

### (Structure)

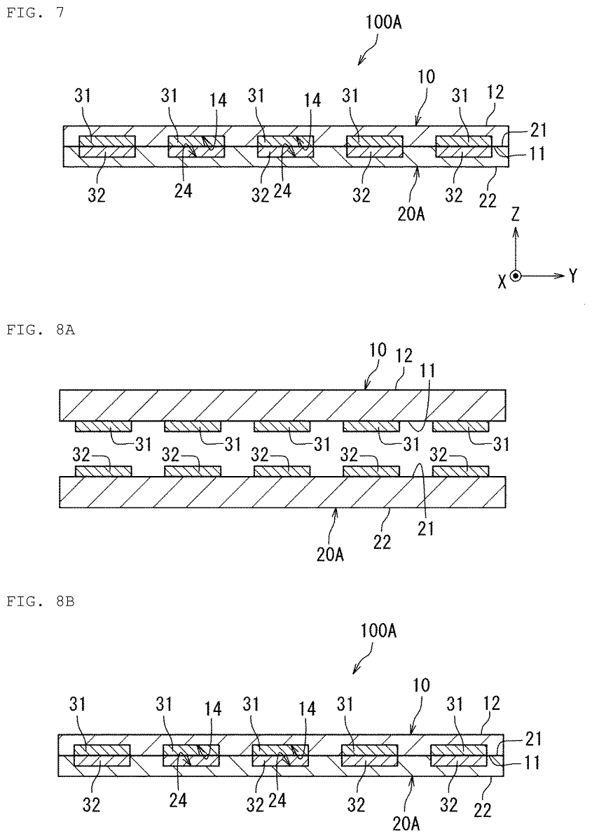

Next, a second embodiment will be described with reference to FIG. 7. FIG. 7 is a sectional view of a wiring board 100A according to the second embodiment. FIG. 7 corresponds to FIG. 4 of the first embodiment. The wiring board 100A according to the second embodiment is different from the wiring board 100 according to the first embodiment in a structure of a second substrate 20A.

As illustrated in FIG. 7, the second substrate 20A has the second main surface 21 and the fourth main surface 22 located on the opposite side to each other. The first substrate 10 has the first recessed portion 14 on the first main surface 11, and the second substrate 20A has a second recessed portion 24 on the second main surface 21. The first wiring 31 is arranged in the first recessed portion 14, and the second wiring 32 is arranged in the second recessed portion 24. One of the first wirings 31 is arranged in one of the first recessed portions 14. One of the second wirings 32 is arranged in one of the second recessed portions 24.

According to the above configuration, since the first wiring 31 is arranged in the first recessed portion 14, the first substrate 10 exists between two of the first wirings 31 adjacent to each other in the Y direction. By this, insulation between two of the first wirings 31 adjacent to each other can be ensured. Similarly, since the second wiring 32 is arranged in the second recessed portion 24, the second substrate 20A exists between two of the second wirings 32 adjacent to each other in the Y direction. By the above, insulation between two of the second wirings 32 adjacent to each other can be ensured.

In the structure described above, the recessed portions 14 and 24 are provided in the first substrate 10 and the second substrate 20A, respectively, and the wirings 31 and 32 are arranged in the recessed portions 14 and 24. By the above, since thickness of the first substrate 10 and the second substrate 20A can be further reduced, the wiring board can be further reduced in thickness.

The second substrate 20A is a substrate having similar stretchability to that of the first substrate 10, and is, for example, thermoplastic resin. Specifically, examples of the thermoplastic resin include thermoplastic polyurethane (TPU), polyethylene (PE), and the like. The thermoplastic resin has a softening point, and for example, the softening point is 90° C. or more. A shape of the second substrate 20A is preferably a sheet shape or a film shape. Thickness of the second substrate 20A is not particularly limited, but is preferably 160 μm or less, and more preferably 80 μm or less, from the viewpoint of not inhibiting expansion and contraction of a surface of a living body at the time of attachment to the living body. Further, the thickness of the second substrate 20A is more preferably 40 μm or more. A material of the second substrate 20A is preferably the same material as the first substrate. By using the same material as the first substrate 10, an amount of expansion and contraction of the entire wiring board can be made close to a uniform amount. Note that the first substrate 10 and the second substrate 20A may be of different materials.

Further, according to the present embodiment, as in the first embodiment, a distance between the second wiring 32 and the fourth main surface 22 of the second substrate 20A can also be reduced for the second substrate 20A. That is, since thickness of the second substrate 20A at a portion overlapping the second wiring 32 as viewed from the Z direction can be reduced, in a case where the second substrate 20A has stretchability, the stretchability of the second substrate 20A is improved.

Preferably, the first main surface 11 and the second main surface 21 are in contact with and bonded to each other. Preferably, the first wiring 31 and the second wiring 32 face each other in the Z direction and are in contact with each other. Preferably, an interface between the first wiring 31 and the second wiring 32 and an interface between the first main surface 11 and the second main surface 21 are located on the same plane in sectional view. That is, a contact surface between the wirings and a contact surface between the substrates are located on the same plane. When the interfaces coincide with each other, amounts of expansion and contraction on the first substrate 10 side and on the second substrate 20A side can be made closer to uniformity. Note that an interface between the first wiring 31 and the second wiring 32 and an interface between the first main surface 11 and the second main surface 21 do not need to be located on the same plane.

### (Manufacturing Method)

Next, a method for manufacturing the wiring board 100A will be described with reference to FIGS. 8A and 8B.

As illustrated in FIG. 8A, a plurality of the first wirings 31 are formed on the first main surface 11 of the first substrate 10. Similarly, a plurality of the second wirings 32 are formed on the second main surface 21 of the second substrate 20A. The first substrate 10 and the second substrate 20A are stacked in a manner that the first wiring 31 and the second wiring 32 face each other in the Z direction. Then, a heater is pressed against each of the third main surface 12 of the first substrate 10 and the fourth main surface 22 of the second substrate 20A, and the first substrate 10 and the second substrate 20A are heated by the heater.

As illustrated in FIG. 8B, the first substrate 10 flows between two of the first wirings 31 adjacent to each other by pressurization and heating by the heater. Further, the second substrate 20A flows between two of the second wirings 32 adjacent to each other. The first substrate 10 and the second substrate 20A that flow are in contact with each other while covering the first wiring 31 and the second wiring 32. By this, the first main surface 11 of the first substrate 10 and the second main surface 21 of the second substrate 20A are thermocompression-bonded. The first wiring 31 is arranged in the first recessed portion 14, and the second wiring 32 is arranged in the second recessed portion 24. Since the first substrate 10 and the second substrate 20A have a softening point, the first substrate 10 and the second substrate 20A easily flow when heated, and easily come into contact with each other. That is, thermocompression bonding is suitably performed. Further, since the first substrate 10 and the second substrate 20A have thermoplasticity, which is similarly suitable for thermocompression bonding.

### Third Embodiment

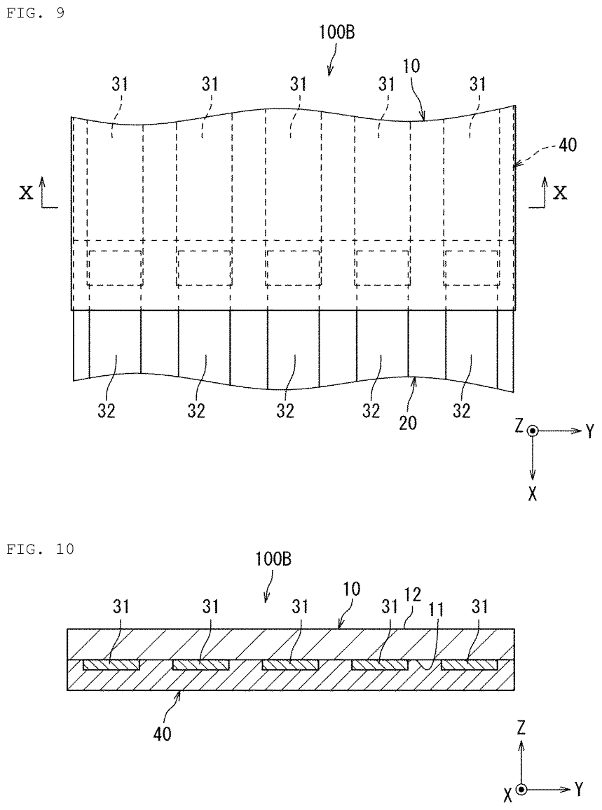

Next, a wiring board 100B according to a third embodiment will be described with reference to FIGS. 9 and 10. FIG. 9 is a plan view of the wiring board according to the third embodiment. FIG. 10 is a sectional view taken along line X-X of FIG. 9. The wiring board 100B according to the third embodiment is different from the wiring board 100 according to the first embodiment in that an insulating layer 40 is provided.

As illustrated in FIG. 10, at least a part of the first wiring 31 arranged on the first main surface 11 of the first substrate 10 is covered with the insulating layer 40. Preferably, the first main surface 11 located between two of the first wirings 31 adjacent to each other is also covered with the insulating layer 40. As the first wiring 31 is covered with the insulating layer 40, entry of water from the outside into the first wiring 31 can be suppressed, and a short circuit to the first wiring 31 may also be prevented.

The insulating layer 40 may extend along the X direction as viewed from the thickness direction (Z direction) of the first substrate. Thickness of the insulating layer 40 is not particularly limited, but the thickness of the insulating layer 40 is preferably 40 μm to 80 μm in order to suppress entry of water and achieve reduction in thickness.

A material of the insulating layer 40 may be an insulating material of an acrylic oligomer or a urethane acrylate base material. The insulating layer 40 is preferably a low water absorption insulating layer or the like containing low water absorption insulating resin such as silicone resin, acrylic resin, olefin resin, modified urethane resin, vinyl chloride resin, polyester, polyamide, polyolefin, polyethylene, or polypropylene, or a paraxylylene-based polymer. A shape of the insulating layer 40 is a sheet shape or a film shape.

### Fourth Embodiment

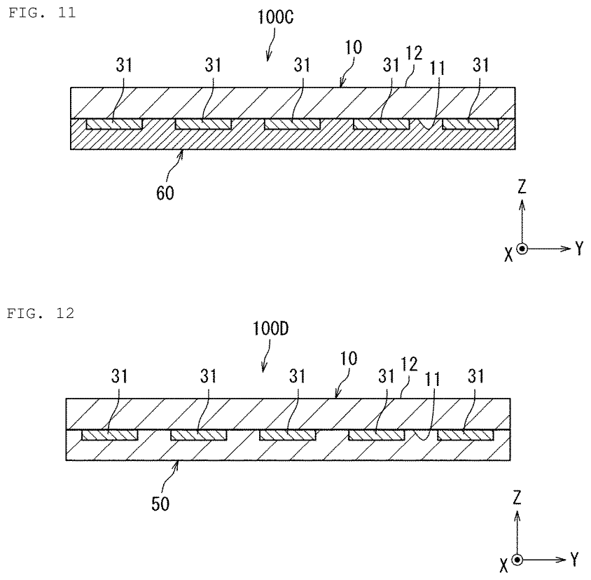

Next, a wiring board 100C according to a fourth embodiment will be described with reference to FIG. 11. FIG. 11 is a sectional view of the wiring board according to the fourth embodiment. FIG. 11 corresponds to FIG. 10 of the third embodiment. The wiring board 100C according to the fourth embodiment is different from the wiring board 100 according to the first embodiment in that a covering layer 60 is provided.

As illustrated in FIG. 11, at least a part of the first wiring 31 is covered with the covering layer 60. Preferably, the first main surface 11 located between two of the first wirings 31 adjacent to each other is also covered with the covering layer 60. By the above, entry of water from the outside can be suppressed in the first wiring 31. The covering layer 60 extends along the X direction when viewed in the thickness direction (Z direction) of the first substrate. Thickness of the covering layer 60 is not particularly limited, but the thickness of the covering layer 60 is preferably 40 μm to 80 μm from the viewpoint of achieving both suppression of entry of water and reduction in thickness.

A material of the covering layer 60 is not particularly limited, but may be, for example, a laminate. A material of the laminate is, for example, a stretchable film of an adhesive type, high-adhesion crystal gel, or an ultra-thin PDMS sheet. According to such a material, biocompatibility of the wiring board is improved. For example, when the wiring board 100C is used in a manner that the covering layer 60 is in contact with a living body, possibility that the living body exhibits a foreign substance reaction, a rejection reaction, or the like can be reduced because the covering layer 60 has affinity for a living tissue. A shape of the covering layer 60 is a film shape or a sheet shape.

### Fifth Embodiment

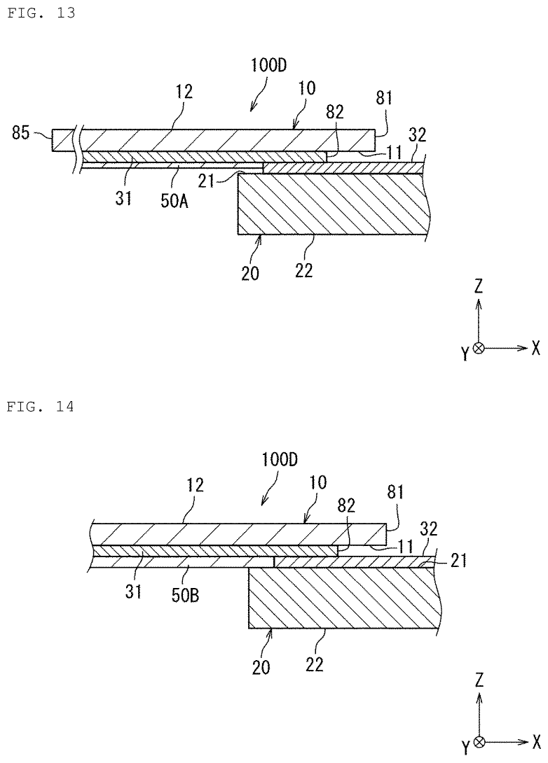

A wiring board 100D according to a fifth embodiment will be described with reference to FIG. 12. FIG. 12 is a sectional view of a wiring board according to the fifth embodiment. FIG. 12 corresponds to FIG. 10 of the third embodiment. The wiring board 100D according to the fifth embodiment is different from the wiring board 100 according to the first embodiment in that a thermoplastic sheet 50 is provided.

As illustrated in FIG. 12, at least a part of the first wiring 31 is covered with the thermoplastic sheet 50, and the thermoplastic sheet 50 is in contact with and bonded to the first main surface 11. Specifically, the first main surface 11 located between the first wirings 31 adjacent to each other is also covered with the thermoplastic sheet 50. By this, entry of water into the first wiring 31 is suppressed. Furthermore, connection strength between the thermoplastic sheet 50 and the first wiring 31 is improved, and the first wiring 31 can be firmly fixed to the first substrate 10.

Examples of a material of the thermoplastic sheet 50 include thermoplastic resin. Specifically, thermoplastic polyurethane (TPU), polyethylene (PE), and the like are included. A shape of the thermoplastic sheet 50 is a sheet shape or a film shape. From the viewpoint of reducing overall thickness of the wiring board, thickness of the thermoplastic sheet 50 is preferably 160 μm or less. Materials of the thermoplastic sheet 50 and the first substrate 10 may be the same or different.

### First Variation

FIG. 13 is a sectional view of a first variation of the wiring board according to the fifth embodiment. As illustrated in FIG. 13, a thermoplastic sheet 50A covers the first wiring 31, is in contact with and bonded to the first main surface 11, and further is in contact with and bonded to the second wiring 32. By the above, connection strength between the thermoplastic sheet 50A and the second wiring 32 is increased.

Alternatively, the thermoplastic sheet 50A may be separated from the second wiring 32. In the sectional view illustrated in FIG. 13, a gap may be provided between the thermoplastic sheet 50A and the second wiring 32. More specifically, in a region overlapping the first substrate 10 and the second substrate 20, an end edge of the thermoplastic sheet 50A and an end edge of the second wiring 32 may be separated with a gap interposed therebetween. This can also be understood that the thermoplastic sheet 50A is provided so as to be separated from a connection portion between the first wiring 31 and the second wiring 32. According to such a structure, it is possible to prevent the thermoplastic sheet 50A from reaching the connection portion between the first wiring 31 and the second wiring 32 when the thermoplastic sheet 50A is deformed or flows due to heat at the time of thermocompression bonding or the like. That is, by separating the thermoplastic sheet 50A and the second wiring 32 from each other, the possibility that the thermoplastic sheet 50A obstructs connection between wirings is reduced, so that connection reliability between the wirings may be further improved.

Preferably, in a region overlapping the first substrate 10 and the second substrate 20 when viewed from the thickness direction (Z direction) of the first substrate, an end edge 81 in an extending direction of the first substrate 10 extends past an end edge of the first wiring 31. Specifically, the first substrate 10 has another end edge 85 on the opposite side to the end edge 81 in the extending direction, and the end edge 81 is farther from the other end edge 85 than the end edge 82. By the above, the first wiring 31 can be prevented from being exposed from the first substrate 10, and the first wiring 31 can be protected by the first substrate 10.

### Second Variation

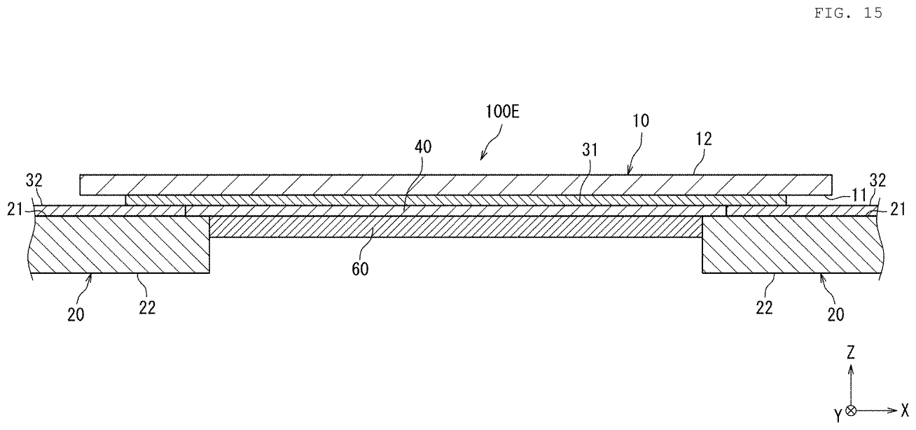

FIG. 14 is a sectional view of a second variation of the wiring board according to the fifth embodiment. As illustrated in FIG. 14, a thermoplastic sheet 50B covers the first wiring 31, is in contact with and bonded to the first main surface 11, and is in contact with and bonded to the second wiring 32 and the second substrate 20. That is, the thermoplastic sheet 50B may be arranged so as to be sandwiched between the first substrate 10 and the second substrate 20, and may be in contact with and bonded to both the first main surface 11 and the second main surface 21. By this, connection strength between the thermoplastic sheet 50B and the second substrate 20 is increased. Furthermore, bonding strength between the first substrate 10 and the second substrate 20 may also be improved. In such a structure, the thermoplastic sheet 50B may have the same thickness as the second wiring 32. More specifically, the thermoplastic sheet 50B may have the same thickness as the second wiring 32 at least in a region where the first substrate 10 and the second substrate 20 overlap. Note that, at this time, the thermoplastic sheet 50B does not need to be in contact with the second wiring 32.

Thickness of the thermoplastic sheet may be smaller than that of the second wiring 32 as illustrated in FIG. 13, or may be equal to that of the second wiring 32 as illustrated in FIG. 14. Alternatively, from the viewpoint of placing more importance on protection of the wiring, the thermoplastic sheet may have thickness larger than that of the second wiring 32.

Further, in the sectional views illustrated in FIGS. 13 and 14, thickness of the thermoplastic sheet is not necessarily uniform in the X direction. For example, the thermoplastic sheet may have smaller thickness in a region where the first board 10 and the second board 20 overlap each other than other regions. More specifically, the thermoplastic sheet may have smaller thickness at a portion proximal to a connection point between the first wiring 31 and the second wiring 32. That is, the thermoplastic sheet may have smaller thickness in a region where a plurality of members overlap. By this, thickness of the entire wiring board in a region where a plurality of members overlap can be reduced, so that the wiring board can be reduced in thickness.

Further, the thermoplastic sheet as described above may also be provided on the second substrate 20 overlapping the first substrate 10. That is, the second substrate may include a thermoplastic sheet that covers the second wiring 32 and is in contact with and bonded to the second main surface 21. The thermoplastic sheet covering the second wiring 32 may be in contact with and bonded to the first wiring 31. Alternatively, the thermoplastic sheet covering the second wiring 32 may be separated from the first wiring 31. As each of the first wiring 31 and the second wiring 32 is covered with the thermoplastic sheet, it is possible to obtain an effect of suppressing entry of water into each wiring and improving bonding strength between the wiring and the substrate.

The wiring having a portion covered with covering members such as the thermoplastic sheet, the insulating layer, and/or the covering layer described above does not necessarily have uniform thickness. The wiring may have different thicknesses at an overlapping portion overlapping the covering member and a non-overlapping portion not overlapping the covering member. Such “overlapping portion” and “non-overlapping portion” can also be referred to as “covered portion” and “non-covered portion”, respectively. For example, the wiring may have smaller thickness in the overlapping portion than in the non-overlapping portion. In other words, thickness of the wiring in the non-overlapping portion may be larger than thickness of the wiring in the overlapping portion. In the overlapping portion, the wiring is suitably protected by the covering member and is more suitably in close contact with a substrate, so that the wiring can have relatively small thickness. Since the wiring has small thickness, it is possible to further reduce thickness of the wiring board.

### Sixth Embodiment

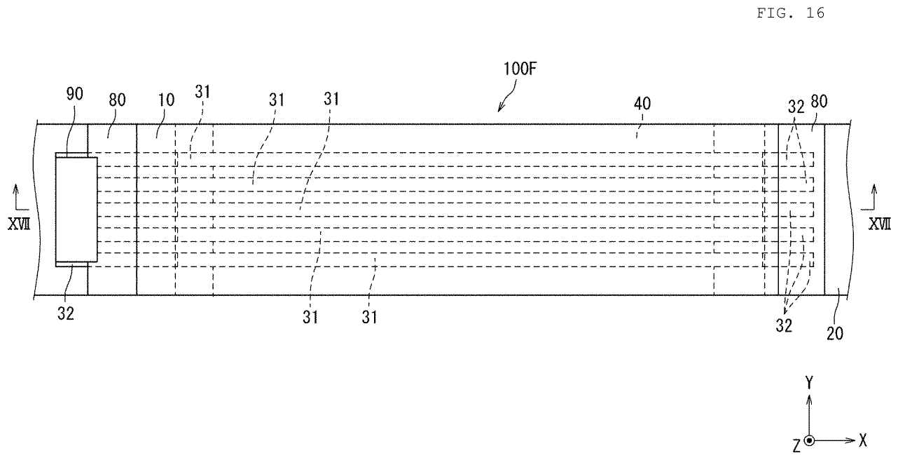

Next, a wiring board 100E according to a sixth embodiment will be described with reference to FIG. 15. FIG. 15 is a sectional view of the wiring board according to a sixth embodiment. The wiring board 100E according to the sixth embodiment is different from the wiring board 100B according to the third embodiment in that the covering layer 60 is further provided.

As illustrated in FIG. 15, the insulating layer 40 is covered with the covering layer 60. A material of the covering layer 60 is different from that of the insulating layer 40. The covering layer 60 extends along the X direction as viewed from the thickness direction (Z direction) of the first substrate.

By the above, deterioration of the insulating layer 40 can be prevented, and leakage of a component contained in the insulating layer 40 can be prevented. Preferably, the covering layer 60 is bonded to the insulating layer 40 by an adhesive. Further, the covering layer 60 may be bonded to the second substrate 20.

The covering layer 60 may be, for example, a laminate. A material of the covering layer 60 is, for example, a material such as a hydrocarbon-based material, a urethane gel tape, or silicone elastomer. According to such a material, biocompatibility of the wiring board is improved. For example, when the wiring board 100E is used in a manner that the covering layer 60 is in contact with a living body, the living body can be prevented from exhibiting a foreign substance reaction, a rejection reaction, or the like because the covering layer 60 has affinity for a living tissue. Further, thickness of the covering layer 60 is preferably 20 μm to 80 μm from the viewpoint of achieving both improvement in biocompatibility and reduction in thickness of the wiring board.

### Seventh Embodiment

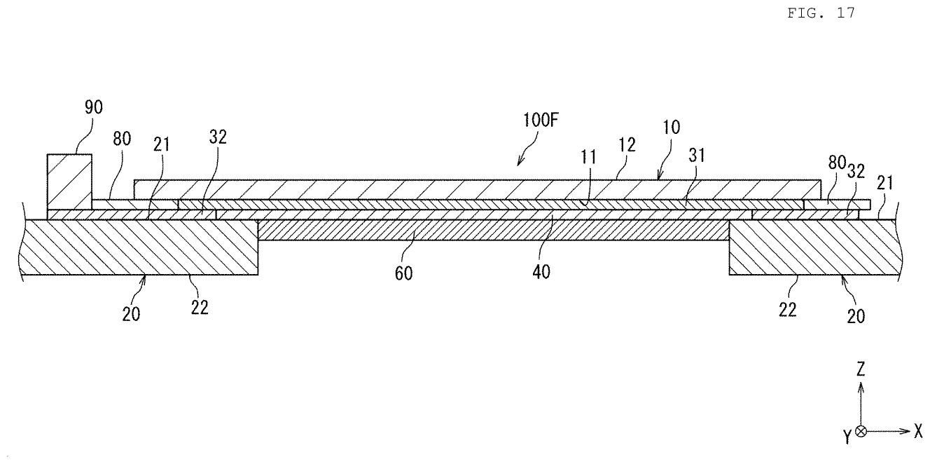

Next, a wiring board 100F according to a seventh embodiment will be described with reference to FIGS. 16 and 17. FIG. 16 is a plan view of the wiring board according to the seventh embodiment. FIG. 17 is a sectional view taken along XVII-XVII of FIG. 16. The wiring board 100F according to the seventh embodiment is different from the wiring board 100E according to the sixth embodiment in that an electronic component 90 and a resist 80 are provided.

As illustrated in FIGS. 16 and 17, the resist 80 is arranged between the first substrate 10 and the second substrate 20 in the thickness direction (Z direction) of the first substrate. Specifically, the resist 80 is in contact with the first main surface 11 and the second main surface 21. Furthermore, the resist 80 does not exist between the first main surface 11 and the first wiring 31, and the resist 80 does not exist between the second main surface 21 and the second wiring 32. For example, a resist may be arranged so as to be in contact with both the second wiring 32 arranged on the second main surface 21 and the first main surface 11. By the above, a space between the first substrate 10 and the second substrate 20 can be filled with the resist 80, so that a foreign matter can be prevented from adhering to the first wiring 31 from the outside.

A material of the resist 80 is not particularly limited, and is, for example, a material such as a liquid epoxy solder resist, an alkali development type solder resist, a UV curing type solder resist, or a thermosetting solder resist. A shape of the resist 80 is not particularly limited, but may be a film shape or a sheet shape.

The electronic component 90 is electrically connected to the second wiring 32. The number of the second wirings 32 electrically connected to the electronic component 90 is not particularly limited, but may be connected to one or a plurality of the second wirings 32. A type of the electronic component 90 is not particularly limited, and is, for example, an inductor, a capacitor, or the like. The number of the electronic components 90 is not particularly limited. A large number of the electronic components 90 may be mounted as necessary.

### Eighth Embodiment

Next, a wiring board 100G according to an eighth embodiment will be described with reference to FIG. 18. FIG. 18 is a sectional view of the wiring board according to the eighth embodiment. FIG. 18 corresponds to FIG. 4 of the first embodiment. The wiring board 100G according to the eighth embodiment is different from the wiring board 100 according to the first embodiment in a width of a first wiring 31A.

As illustrated in FIG. 18, the first wiring 31A and the second wiring 32 are in contact with each other. In the region 70 where the first substrate 10 and the second substrate 20 overlap, a width L3 of the first wiring 31A is smaller than the width L1 of the second wiring 32. By the above, a contact area between the first substrate 10 and the second wiring 32 becomes large, and connection strength between the first substrate 10 and the second wiring 32 is improved.

Here, the width L3 of the first wiring 31A is size in a direction orthogonal to an extending direction of the first wiring 31A when viewed from the Z direction. That is, the width L3 of the first wiring 31A is size in the Y direction of the first wiring 31A. The width L3 of the first wiring 31A is a maximum value of a width of the first wiring 31A. In a case where it is difficult to measure a maximum value in the first wiring 31A, an average value of widths of the first wiring 31A is set to L3.

Here, the width L1 of the second wiring 32 is size in a direction orthogonal to an extending direction of the second wiring 32 when viewed from the Z direction. That is, the width L1 of the second wiring 32 is size in the Y direction of the second wiring 32. The width L1 of the second wiring 32 is a maximum value of a width of the second wiring 32. In a case where it is difficult to measure a maximum value in the second wiring 32, an average value of widths of the second wirings 32 is set to L1.

The average value refers to an average value of measurement values obtained by measuring widths at three different points along the extending direction (X direction) for one of the first wirings 31A in a region where the first substrate 10 and the second substrate 20 overlap.

### Ninth Embodiment

Next, a wiring board 100H according to a ninth embodiment will be described with reference to FIG. 19. FIG. 19 is a sectional view of the wiring board according to the ninth embodiment. FIG. 19 corresponds to FIG. 4 of the first embodiment. The wiring board 100H according to the ninth embodiment is different from the wiring board 100 according to the first embodiment in a shape of the third main surface 12.

As illustrated in FIG. 19, the first substrate 10 is in contact with and bonded to the second substrate 20. The first substrate 10 covers the first wiring 31 and the second wiring 32. In the first substrate 10, a shape of the third main surface 12 located on the opposite side to the first main surface in contact with the first wiring 31 is uneven. By this, a surface area of the third main surface 12 of the first substrate 10 becomes large, and heat dissipation of the first wiring 31 is improved. Further, at the time of thermocompression bonding of the first substrate 10 and the second substrate 20 at the time of manufacturing of the wiring board, a heater and a projecting portion of the third main surface 12 come into contact with each other, and heat can be intensively applied to a projecting portion of the first substrate 10. This makes it possible to quickly perform thermocompression bonding.

As illustrated in FIG. 19, the third main surface 12 has a projecting shape in a region overlapping the first wiring 31 when viewed from the Z direction, and has a recessed shape in a region between two of the first wirings 31 adjacent to each other. That is, the third main surface 12 is formed along the first wiring 31 and the second main surface 21 between the two of the first wirings 31 adjacent to each other.

### Tenth Embodiment

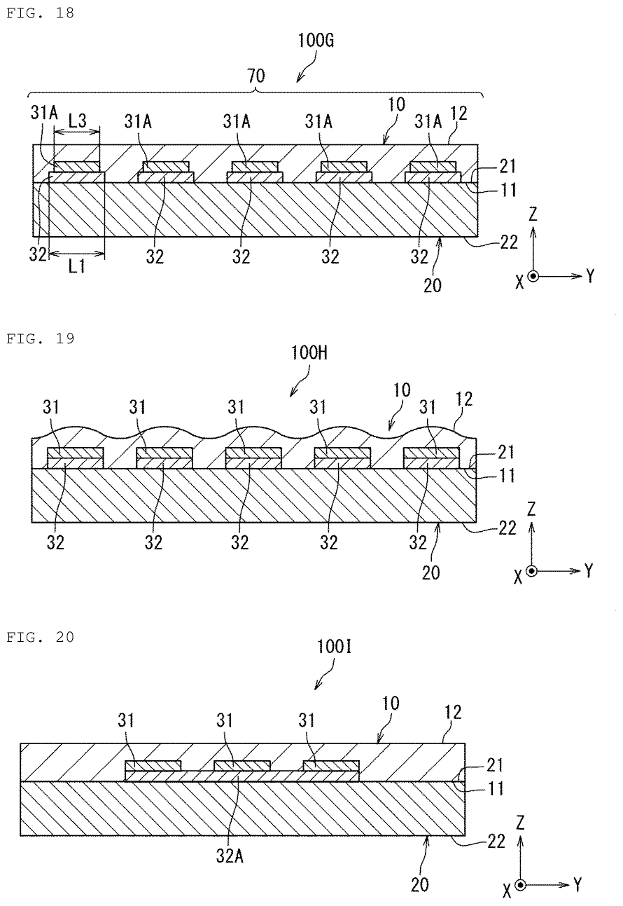

Next, a wiring board 100I according to a tenth embodiment will be described with reference to FIG. 20. FIG. 20 is a sectional view of the wiring board according to the tenth embodiment. FIG. 20 corresponds to FIG. 4 of the first embodiment. The wiring board 100I according to the tenth embodiment is different from the wiring board 100 according to the first embodiment in size and the number of second wirings 32A.

As illustrated in FIG. 20, a plurality of the first wirings 31 and one of the second wiring 32A are electrically connected so as to face each other in thickness direction (Z direction) of the first substrate. That is, among a plurality of the first wirings 31 arranged on the first main surface 11, at least two of the first wirings 31 may be electrically connected to the same second wiring 32A. Specifically, a width in the Y direction of the second wiring 32A is larger than a width in the Y direction of the first wiring 31, and two or more of the first wirings 31 are connected to one of the second wiring 32A. The second wiring 32A may extend in the Y direction so as to be mutually connected to each of a plurality of first wirings 31 parallel to each other in the Y direction. A plurality of the first wirings 31 adjacent to each other are separated from each other. By this, the number of the second wirings 32A for a plurality of the first wirings 31 is reduced, and degree of freedom in designing the wiring board 100I is increased.

A part of the first substrate 10 is arranged between a plurality of the first wirings 31 adjacent to each other and is in contact with the second wiring 32A. By the above, insulation between the first wirings 31 adjacent to each other is ensured. Note that a form of connection between the first wiring 31 and the second wiring 32A is not particularly limited. For example, a plurality of the second wirings may be electrically connected to one of the first wiring. At this time, the second substrate 20 is preferably the same material as the first substrate 10.

Note that the present disclosure is not limited to the above-described embodiment, and can be changed in design without departing from the gist of the present disclosure. For example, feature points of the first to tenth embodiments may be combined in various ways.

### DESCRIPTION OF REFERENCE SYMBOLS

100, 100A, 100B, 100C, 100D, 100E, 100F, 100G, 100H, 100I: Wiring board
10: First substrate
11: First main surface
11a: Flat surface
11b: Extended surface
12: Third main surface
20, 20A: Second substrate
21: Second main surface
22: Fourth main surface
31, 31A: First wiring
32, 32A: Second wiring
40: Insulating layer
50, 50A, 50B: Thermoplastic sheet
60: Covering layer
70: Region where first substrate and second substrate overlap
71: Region of second wiring
72: Region between two second wirings adjacent to each other
80: Resist
81: End edge of first substrate
82: End edge of first wiring
85: Another end edge
90: Electronic component
L1: Width of second wiring
L2: Width between second wirings
L3: Width of first wiring
D1: Distance from first wiring to third main surface
D2: Distance from interface between first substrate and second substrate to third main surface
X: Extending direction of first substrate
Z: Thickness direction of first substrate

1. A wiring board comprising:
a first substrate having a first main surface;
a second substrate having a second main surface;
a first wiring on the first main surface; and
a second wiring on the second main surface,
wherein
the first main surface and the second main surface are in contact with each other, and the first substrate and the second substrate are connected to each other, and
the first wiring and the second wiring face each other in a thickness direction of the first substrate and are electrically connected to each other.

2. The wiring board according to claim 1, wherein
the first substrate has a first recessed portion on the first main surface, and
the first wiring and the second wiring are in the first recessed portion.

3. The wiring board according to claim 1, wherein an interface between the first wiring and the second wiring and an interface between the first main surface and the second main surface are located on different planes along the thickness direction.

4. The wiring board according to claim 1, wherein
the first substrate has a third main surface, and
in the thickness direction, a distance from the first wiring to the third main surface is shorter than a distance from an interface between the first substrate and the second substrate to the third main surface.

5. The wiring board according to claim 1, wherein the first substrate has a first recessed portion on the first main surface, the second substrate has a second recessed portion on the second main surface, the first wiring is in the first recessed portion, and the second wiring is in the second recessed portion.

6. The wiring board according to claim 1, further comprising an insulating layer covering at least a part of the first wiring.

7. The wiring board according to claim 1, further comprising a covering layer covering at least a part of the first wiring.

8. The wiring board according to claim 1, further comprising a thermoplastic sheet covering at least a part of the first wiring, the thermoplastic sheet being in contact with and bonded to the first main surface.

9. The wiring board according to claim 8, wherein the thermoplastic sheet is further in contact with and bonded to the second wiring.

10. The wiring board according to claim 8, wherein the thermoplastic sheet is further in contact with and bonded to the second main surface.

11. The wiring board according to claim 6, further comprising:
a covering layer covering at least a part of the insulating layer,
wherein a material of the covering layer is different from a material of the insulating layer.

12. The wiring board according to claim 1, wherein in a region where the first substrate and the second substrate overlap as viewed in the thickness direction, a first end edge in an extending direction of the first substrate extends past a second end edge of the first wiring in the extending direction.

13. The wiring board according to claim 1, further comprising a resist between the first substrate and the second substrate in the thickness direction.

14. The wiring board according to claim 1, wherein a plurality of the second wirings are arranged side by side in a region where the first substrate and the second substrate overlap, and a ratio L1/L2 of a width L1 of the second wiring and a width L2 between two of the second wirings adjacent to each other is 1 to 20.

15. The wiring board according to claim 1, wherein in a region where the first substrate and the second substrate overlap, a width L3 of the first wiring is smaller than a width L1 of the second wiring.

16. The wiring board according to claim 1, wherein
the first substrate has a third main surface, and
a shape of the third main surface is an uneven shape.

17. The wiring board according to claim 1, wherein a plurality of the first wirings and one of the second wirings face each other in the thickness direction and are electrically connected to each other.

18. The wiring board according to claim 17, wherein a part of the first substrate is between the plurality of first wirings adjacent to each other and is in contact with the second wiring.

19. The wiring board according to claim 1, wherein at least the first substrate of the first substrate and the second substrate has a softening point suitable for thermocompression bonding.
